(19) United States
(12) Patent Application Publication
(10) Pub. No.: US 2026/0038766 A1
(43) Pub. Date: Feb. 5, 2026

(54) Ion Milling Device and Processing Method Using Same

(71) Applicant: Hitachi High-Tech Corporation, Minato-ku, Tokyo (JP)

(72) Inventors: Shota AIDA, Tokyo (JP); Hisayuki TAKASU, Tokyo (JP); Atsushi KAMINO, Tokyo (JP); Hitoshi KAMOSHIDA, Tokyo (JP); Naohiro FUJITA, Tokyo (JP)

(21) Appl. No.: 19/099,089

(22) PCT Filed: Aug. 10, 2022
(86) PCT No.: PCT/JP2022/030559

§ 371 Date: Jan. 28, 2025

(51) Int. Cl. H01J 37/305; H01J 37/08; H01J 37/20

(52) U.S. Cl. CPC H01J 37/3056; H01J 37/08; H01J 37/20; H01J 2237/20207; H01J 2237/20214

(57) ABSTRACT

An ion milling device includes: a sample chamber (109); a sample stage (102) tiltable about a tilt axis (T) and configured to allow a sample (120) to be placed thereon via a rotation stage (103) rotating about a rotation axis (R) and a three-axis drive stage (104) that can be driven in three axial directions perpendicular to one another; an ion source (101) configured to emit an unfocused ion beam to the sample and attached to the sample chamber such that an ion beam center (B) of the ion beam is perpendicular to the tilt axis (T); and a first finder (105). An optical system of the first finder is disposed on the sample stage such that an optical axis of the optical system coincides with the tilt axis (T).

### TECHNICAL FIELD

The present invention relates to an ion milling device and a processing method using the ion milling device.

### BACKGROUND ART

An ion milling device emits an unfocused ion beam to a sample (for example, metal, semiconductors, glass, ceramic, or the like) to be observed by an electron microscope. When atoms on a sample surface are ejected due to a sputtering phenomenon, the sample surface can be polished without stress or an internal structure of the sample can be exposed. The sample surface, that is ion-milled by the emitted ion beam, and the exposed internal structure of the sample serve as observation surfaces of a scanning electron microscope or a transmission electron microscope by irradiation with the ion beam. PTL 1 discloses an ion source position adjustment mechanism that adjusts a position of an ion source attached to a sample chamber in order to cause an ion beam center of an ion beam for processing a sample to coincide with a rotation center of a stage on which the sample is placed.

### CITATION LIST

### Patent Literature

PTL 1: WO2019/167165

### SUMMARY OF INVENTION

### Technical Problem

A method of processing a sample surface by using an ion milling device to emit an ion beam to the sample surface rotated or rotated by half is referred to as plane milling. When plane milling is used, for example, to remove polishing scratches on the sample surface, the ion beam center of the ion beam and the rotation center of the stage are caused to be eccentric, and the ion beam having an ion beam profile with a half width of about 0.5 to 1 mm is usually emitted while rotating the sample. Accordingly, a vicinity of the ion beam center having the highest intensity is not continuously emitted to one location of the sample surface, and therefore, a sample surface that is smooth in a wide range can be obtained.

In contrast, when the ion beam is emitted while rotating the sample without causing the ion beam center of the ion beam and the rotation center of the stage to be eccentric, the ion beam center is normally located at an intersection of the sample surface and the rotation center of the stage, and therefore, a conical hole is formed on the sample surface in this case. Such processing using plane milling is effective for inspection of an internal structure of a three-dimensional device.

For example, in a three-dimensional device such as a flash memory, a FinFET, or a gate all around (GAA) type FET in which a memory cell array is stacked, a fine groove or hole having a high aspect ratio is provided at a high density, and an insulating film, a semiconductor film, a metal film, or the like is stacked on a side wall of the groove or the hole to form an active element. In order to increase a yield of a mass production line of a three-dimensional device having such an internal structure, it is effective to expose the internal structure of the three-dimensional device and analyze and inspect, based on a scanning electron microscope (SEM) image obtained by imaging an internal fine structure, whether a desired internal structure is actually formed.

Here, when the internal structure of the sample is exposed by plane milling using an ion milling device, reproducibility of a shape of a conical hole formed becomes a problem. The processing of a sample by an ion milling device is performed at a high milling rate with an unfocused ion beam, and therefore, real-time control of a processed shape is extremely difficult. In PTL 1, in order to improve the reproducibility of processing, the ion source position adjustment mechanism is provided so that the ion beam center of the ion beam and the rotation center of the stage coincide. The reproducibility of the processing can be improved by setting the eccentricity between the ion beam center and the rotation center to about 20% or less of the half width of the ion beam profile by the ion source position adjustment mechanism.

However, PTL 1 does not provide a unit for easily checking eccentricity between the ion beam center and the rotation center. Even if the eccentricity between the ion beam center and the rotation center is precisely adjusted to 0 in the maintenance of the ion milling device, it is unavoidable that the deviation occurs in a process of repeating the replacement and the processing of a sample. An increase in the deviation between the ion beam center and the rotation center may cause a significant change in the processed shape. Therefore, it is desired that it is possible to easily confirm that the eccentricity is 0 for each sample processing.

When the ion beam is emitted to the sample, the number of atoms ejected by the sputtering phenomenon changes in accordance with incident angles of ions. In order to efficiently perform the processing, generally, the ion beam center of the ion beam and the sample surface are tilted at a predetermined angle (about 60° to 70°) indicating a high sputtering yield in the plane milling. Therefore, the sample stage is provided with a movable mechanism for rotating the sample stage about a tilt axis, and plane milling is performed in a state in which the sample stage is tilted. Therefore, it is desirable to adjust the sample surface to be located on the tilt axis of the sample stage so that the position at which the ion beam is emitted to the sample does not change due to the tilt of the sample. A position at which the radiation position of the ion beam does not change due to the tilt of the sample stage is referred to as an eucentric position, and in the case of the ion milling device, a height of the sample surface is adjusted to a height of the tilt axis of the sample stage which is the eucentric position of the sample stage.

However, even if the height of the sample surface is adjusted to be at the eucentric position of the sample stage during maintenance, the height of the sample surface may deviate from the eucentric position due to variations in the thickness of the sample to be processed or mechanical errors. In the plane milling, the sample stage is tilted at a relatively large angle of about 60° to 70°, and therefore, the error in the eucentric position adjustment largely appears as a deviation in the irradiation position, and accordingly as a deviation in the eccentricity, and the reproducibility of the processed shape deteriorates.

An object of the invention is to enable adjustment of the height of a sample surface to an eucentric position of a sample stage each time a sample is processed by a simple configuration, and to improve reproducibility of processing by an ion milling device.

### Solution to Problem

An ion milling device according to an embodiment of the invention includes: a sample chamber; a sample stage tiltable about a tilt axis and configured to allow a sample to be placed thereon via a rotation stage rotating about a rotation axis and a three-axis drive stage that can be driven in three axial directions perpendicular to one another; an ion source configured to emit an unfocused ion beam to the sample and attached to the sample chamber such that an ion beam center of the ion beam is perpendicular to the tilt axis; and a first finder. An optical system of the first finder is disposed on the sample stage such that an optical axis of the optical system coincides with the tilt axis.

### Advantageous Effects of Invention

An ion milling device having improved reproducibility of a processed shape is provided. Other technical problems and novel features will become apparent from description of the present description and the accompanying drawings.

### BRIEF DESCRIPTION OF DRAWINGS

FIG. 1 is a configuration example (schematic diagram) of an ion milling device.

FIG. 2 is a schematic diagram showing an ion source and a power supply circuit for applying a control voltage to the ion source.

FIG. 3A is a schematic diagram of an ion milling device 100 when viewed from an X-axis direction.

FIG. 3B shows an observation example of a first finder 105 in FIG. 3A.

FIG. 4A is a schematic diagram of the ion milling device 100 when viewed from the X-axis direction.

FIG. 4B shows an observation example of the first finder 105 in FIG. 4A.

FIG. 5A is a schematic diagram of the ion milling device 100 when viewed from a Y-axis direction.

FIG. 5B is an observation example of a second finder 106 in FIG. 5A.

FIG. 6 is a flowchart showing a series of operations from the start of processing to the end of the processing.

### DESCRIPTION OF EMBODIMENTS

Hereinafter, embodiments of the invention will be described with reference to the drawings.

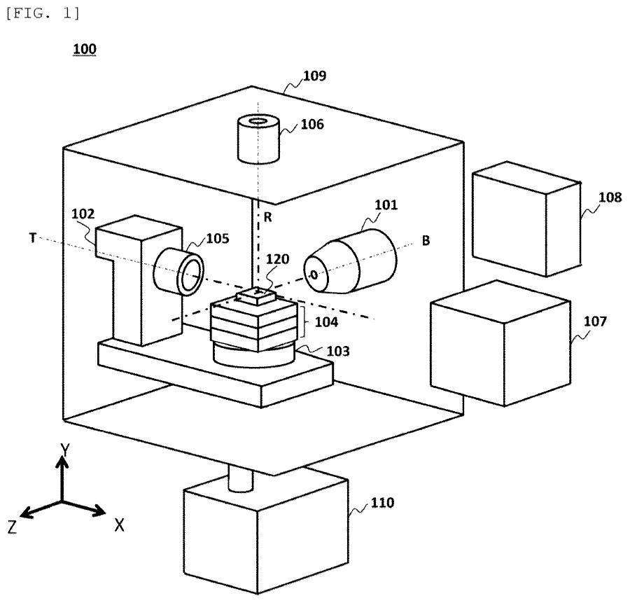

FIG. 1 is a schematic diagram showing main parts of an ion milling device 100. The ion milling device 100 includes an ion source 101, a sample stage 102, a rotation stage 103, a three-axis drive stage 104, a first finder 105, a second finder 106, a control unit 107, a high-voltage power supply unit 108, a sample chamber 109, and a vacuum exhaust unit 110 as main components.

The ion milling device 100 is used as a pretreatment device for observing a sample surface or a sample cross-section with a scanning electron microscope or a transmission electron microscope, and Penning type effective for miniaturization of a device is often employed for an ion source. In the present embodiment, the ion source 101 also employs the Penning type. As will be described in detail below, in the Penning-type ion source 101, electrons are generated by causing Penning discharge by applying a high voltage from the high-voltage power supply unit 108 to an internal electrode, and argon ions are generated by causing the generated electrons to collide with argon gas supplied from the outside. The ion source 101 emits the thus-generated argon ions as an unfocused ion beam to a sample 120 set on the rotation stage 103 and the three-axis drive stage 104. The rotation stage 103 rotates the sample 120 about a rotation axis R. The three-axis drive stage 104 moves the sample 120 in an X-axis direction, a Y-axis direction, and a Z-axis direction. One of the axial directions in which the three-axis drive stage 104 is driven is parallel to the rotation axis R, and FIG. 1 shows an example in which the rotation axis R is parallel to the Y-axis direction in which the three-axis drive stage 104 is driven. The rotation stage 103 and the three-axis drive stage 104 are driven by the control unit 107.

An inside of the sample chamber 109 is maintained at a high vacuum by the vacuum exhaust unit 110, and a stable ion beam can be emitted to the sample 120 without being affected by a gas in the sample chamber. The atoms of the sample 120 are ejected by the sputtering phenomenon caused by argon ions constituting the ion beam, and thus the sample 120 is scraped off. The number of atoms ejected by the sputtering phenomenon changes in accordance with an incident angle of ions relative to the sample 120, and therefore, it is necessary to tilt the sample 120 relative to an ion beam center B of the ion beam in order to efficiently proceed the processing.

The sample stage 102 is provided with a drive mechanism including a motor or the like for rotating the sample stage 102 about the tilt axis T in order to tilt the sample. The sample stage 102 is disposed such that the tilt axis T is perpendicular to the ion beam center B of the ion source. The rotation stage 103 is disposed on the sample stage 102 such that the tilt axis T of the sample stage 102 and the rotation axis R of the rotation stage 103 are perpendicular to each other. The control unit 107 can tilt the sample 120 while maintaining the high vacuum in the sample chamber 109. However, when the sample 120 is not located at the eucentric position of the sample stage 102, a beam irradiation position is eccentric from the rotation axis R when the sample stage 102 is tilted. As described above, a tilt angle is relatively large at about 60° to 70° in the plane milling, and therefore, the eccentricity is also large, and the reproducibility of the processed shape deteriorates.

Therefore, in the ion milling device 100, the first finder 105 is disposed coaxially with the tilt axis T of the sample stage 102 in order to confirm that the surface of the sample 120 is at the eucentric position of the sample stage 102. Specifically, as shown in FIG. 1, an optical system of the first finder is disposed on the sample stage such that an optical axis of the optical system coincides with the tilt axis T. While observing a position of the sample with the first finder 105, the three-axis drive stage 104 is driven in a height direction (corresponding to the Y axis in FIG. 1), and the sample surface is aligned with the eucentric position. Thereafter, the rotation stage 103 is driven to rotate the sample 120. Accordingly, even when the sample is tilted, plane milling in which the eccentricity is 0 can be performed.

Further, in the ion milling device 100 of FIG. 1, the second finder 106 whose optical system has an optical axis extending in the Y-axis direction (a direction perpendicular to a plane extending between the tilt axis T and the ion beam center B) is disposed in the sample chamber 109. The reproducibility of a processing position of the sample 120 can be further improved by checking whether a processing target position of the sample 120 is located on the rotation axis R of the rotation stage 103 by the second finder 106. When the processing target position of the sample 120 deviates from the rotation axis R of the rotation stage 103, the processing target position rotates in accordance with the rotation of the rotation stage 103. Then, while rotating the rotation stage 103, the processing target position of the sample 120 is observed by the second finder 106, so that the three-axis drive stage 104 is adjusted in a plane direction (in the example of FIG. 1, one or both of the X-axis direction and the Z-axis direction) to make the processing target position appear stationary. At this time, the rotation axis R and the processing target position of the sample 120 coincide. According to the above work, even when the sample is tilted, the processing can be performed at a desired processing target position with high reproducibility.

The present embodiment shows an example in which the first finder 105 and the second finder 106 are configured as an optical microscope for checking the sample position according to an optical image. The optical microscope may be one that uses an eyepiece for observation, or one that displays an image formed on an image sensor (such as a CCD or CMOS image sensor) on a monitor. Similarly, a magnifying glass may be used as a unit for checking the sample position from the optical image. In order to enable more precise adjustment, an electron microscope for checking the sample position according to the electron optical image or a white-light interferometer for checking the displacement according to an interference image may be used. The finder can select an exemplified or similar checking unit to enable alignment with a desired precision. The first finder 105 and the second finder 106 may use different optical systems.

For the position adjustment, a user may adjust the three-axis drive stage 104 while visually observing a position of the sample 120 from an image from the finder, or the three-axis drive stage 104 may be automatically adjusted by processing the image captured by the image sensor. In order to check the eucentric position with a high precision, it is desirable that the optical system of the first finder 105 is equipped with a reticle. A crossline indicating a position of the optical axis is displayed on the reticle. In contrast, the reticle may not be provided because the second finder 106 only needs to confirm that the processing target position of the sample 120 is not rotated. In order to adjust the sample surface to the eucentric position with a high precision, it is desirable that a decelerated straight-line helicoid structure with a high adjustment precision is employed for a height-direction drive structure of the three-axis drive stage 104.

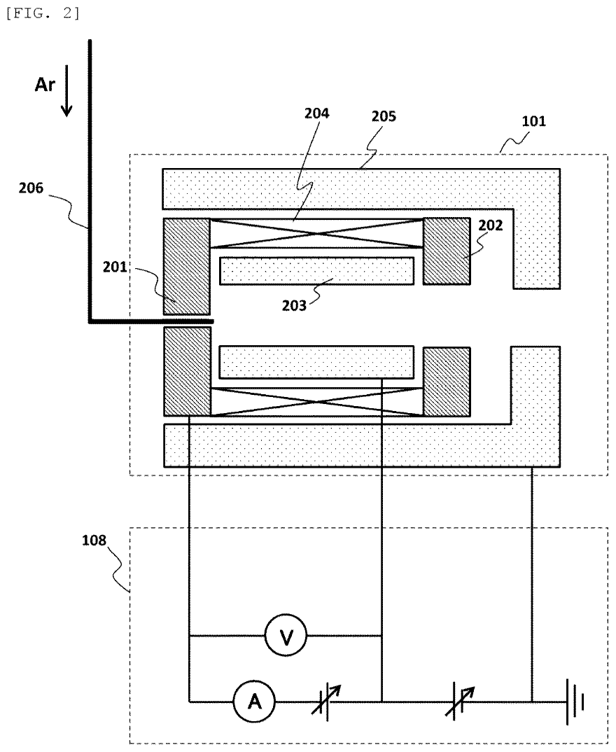

FIG. 2 is a schematic diagram showing the ion source 101 employing the Penning type and a power supply circuit for applying a control voltage to electrode components of the ion source 101. The power supply circuit is a part of the high-voltage power supply unit 108.

The ion source 101 includes a first cathode 201, a second cathode 202, an anode 203, a permanent magnet 204, an acceleration electrode 205, and a gas pipe 206. In order to generate an ion beam, an argon gas is injected into the ion source 101 through the gas pipe 206. In the ion source 101, the first cathode 201 and the second cathode 202 having the same potential are disposed facing each other via the permanent magnet 204, and the anode 203 is disposed between the first cathode 201 and the second cathode 202. A discharge voltage Vd from the high-voltage power supply unit 108 is applied between the cathodes 201 and 202 and the anode 203 to generate electrons. Since the Lorentz force acts on the electrons generated by the permanent magnet 204 disposed in the ion source 101, the electrons perform a spiral motion. The electrons collide with the argon gas injected from the gas pipe 206 to form a plasma, thereby generating argon ions. An acceleration voltage Va from the high-voltage power supply unit 108 is applied between the anode 203 and the acceleration electrode 205, and the generated argon ions are attracted by the acceleration electrode 205 and emitted as an ion beam.

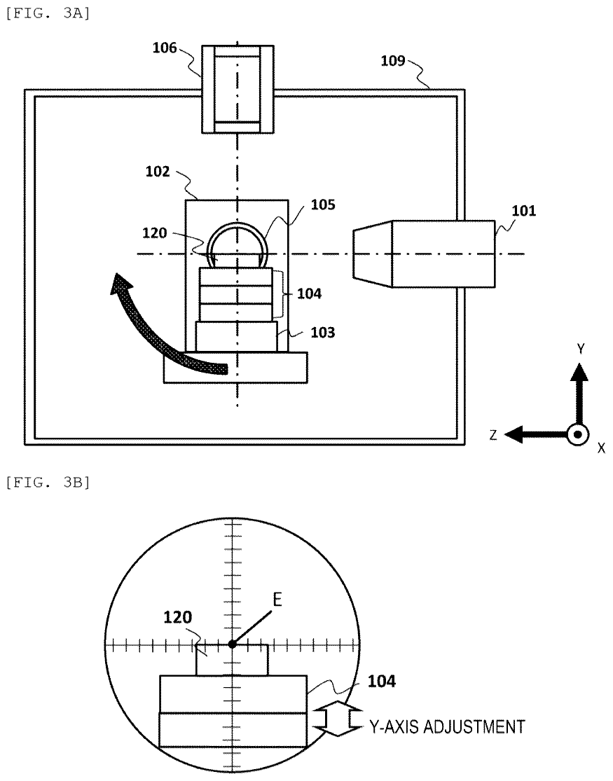

FIG. 3A is a schematic diagram of the ion milling device 100 when viewed from the X-axis direction. FIG. 3A shows a state in which the tilt angle of the sample stage 102 is 0°. In this state, the sample set on the three-axis drive stage 104 is observed by the first finder 105. An observation example of the first finder 105 at this time is shown in FIG. 3B. The optical axis of the optical system of the first finder 105 coincides with the tilt axis T of the sample stage 102, and therefore, a center of the cross line of the reticle is an eucentric position E. The three-axis drive stage 104 is adjusted such that an upper surface of the sample 120 is aligned with the cross line passing through the eucentric position E.

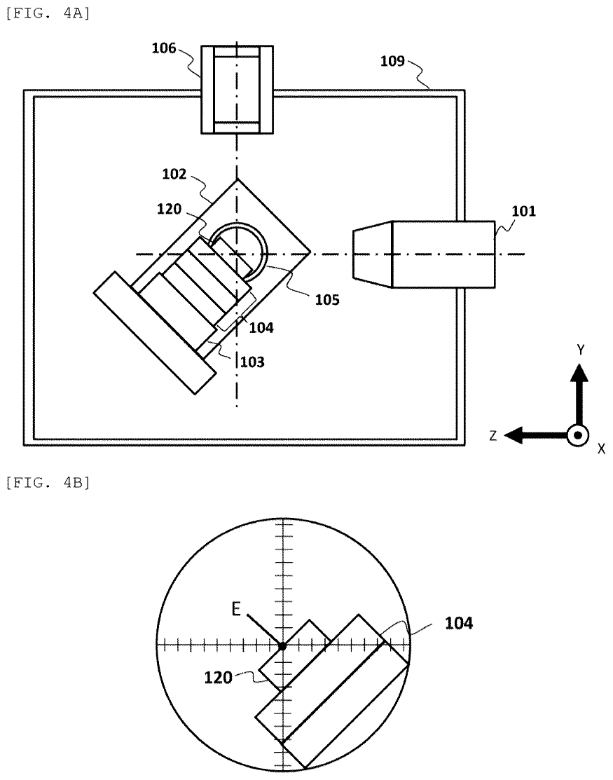

FIG. 4A shows a case in which the tilt angle of the sample stage 102 is set to 45°. An observation example of the first finder 105 at this time is shown in FIG. 4B. When the upper surface of the sample is at the eucentric position E, the upper surface of the sample does not move from the eucentric position E as shown in FIG. 4B even when the sample stage 102 is tilted. When the upper surface of the sample can be aligned with the eucentric position E, the processing position does not become eccentric due to the tilt of the sample stage 102, so that the accuracy of the target processed shape and the precision of the repeated processing can be improved.

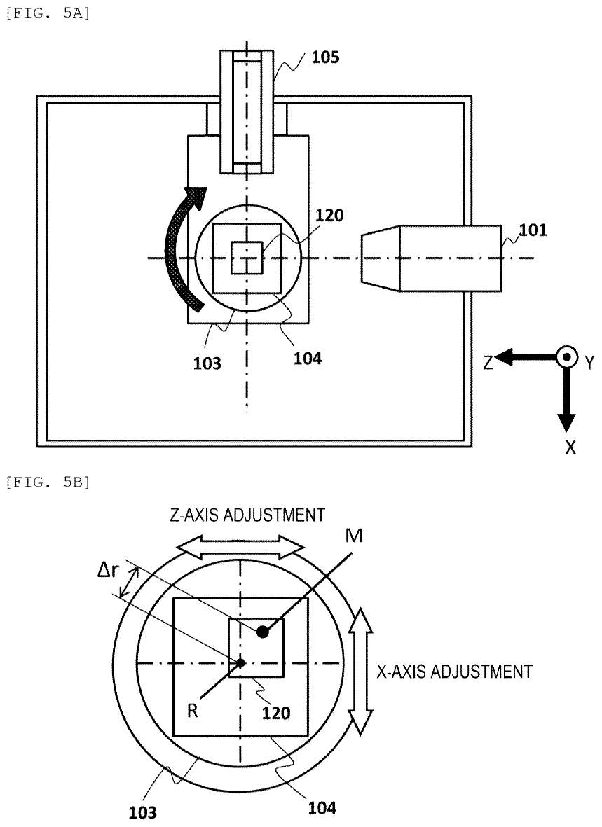

FIG. 5A is a schematic diagram of the ion milling device 100 when viewed from the Y-axis direction. A state in which the tilt angle of the sample stage 102 is 0° is shown. When the rotation stage 103 is rotated, the sample 120 set on the three-axis drive stage 104 is rotated. The sample 120 is marked in advance so that a processing target position can be recognized. However, when the processing target position is clear, it is not necessary to perform the marking. When observation is performed with the second finder 106, a deviation amount Ar between the rotation axis R of the rotation stage 103 and a marking position M of the sample 120 can be checked as shown in FIG. 5B. When the three-axis drive stage 104 is moved in the plane direction (X-axis and Z-axis directions) to cause the rotation axis R of the rotation stage 103 to coincide with the marking position M, the processing target position is located on the rotation axis R. When the upper surface of the sample is aligned with the eucentric position E, the processing position is prevented from becoming eccentric due to the inclination of the sample stage 102, and therefore, a target processed shape can be accurately formed at the marking position M.

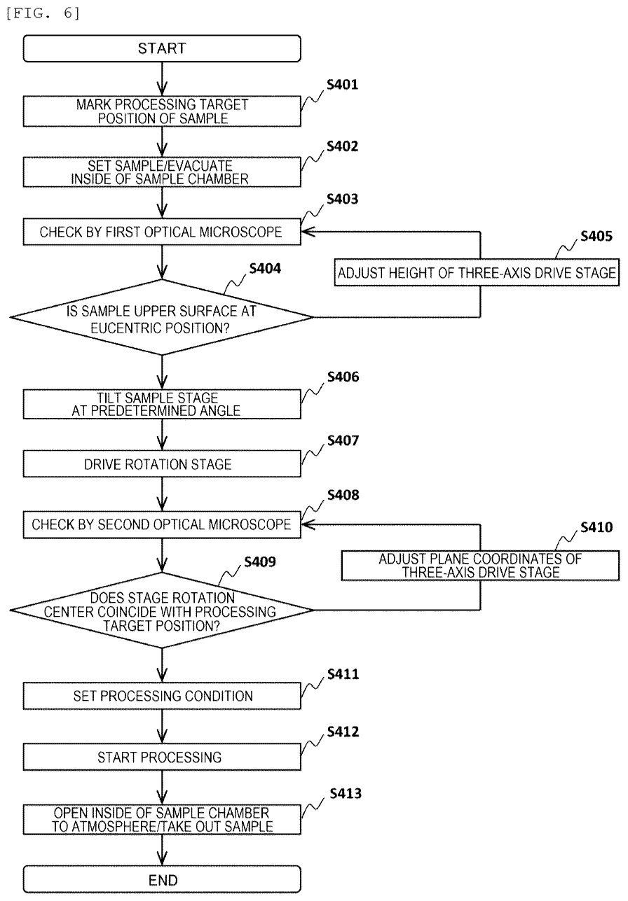

FIG. 6 is a flowchart showing a series of operations from the start to the end of sample processing by the ion milling device 100. Details of each operation are as follows.
S401: A processing target position of the sample 120 is marked. If the processing target position is visible, this operation may be skipped.
S402: The sample 120 is set on the three-axis drive stage 104. After the completion of the setting, the sample chamber 109 is evacuated by the vacuum exhaust unit 110 until the sample chamber 109 becomes a high vacuum.
S403 to S405: A height of the sample set on the three-axis drive stage 104 is checked by the first finder 105 (S403). Whether the upper surface of the sample is at the eucentric position is checked (S404). Specifically, whether the sample surface coincides with the cross line of the reticle is checked on an image in the first finder 105. If the sample surface is not at the eucentric position, the height of the three-axis drive stage 104 is adjusted (S405), and the height of the sample is checked again by the first finder 105 (S403). On the other hand, if the sample surface is at the eucentric position, the processing proceeds to step S406.
S406: The sample stage 102 is tilted to a tilt angle during processing. The tilt angle is set so that the sample 120 is efficiently processed.
S407: The rotation stage 103 is driven.
S408 to S410: The sample 120 set on the three-axis drive stage 104 is checked by the second finder 106 (S408). It is checked whether the processing target position of the sample 120 marked in step S401 is not moved, that is, whether the rotation axis R of the rotation stage 103 coincides with the processing target position of the sample 120 (S409). If they do not coincide, the three-axis drive stage 104 is moved to adjust plane coordinates so that the rotation axis R of the rotation stage 103 and the processing target position of the sample 120 coincide. After the adjustment, the sample 120 is checked again by the second finder 106 (S408). On the other hand, if they coincide, the processing proceeds to step S411.
S411: The acceleration voltage and the discharge voltage for the ion source 101 applied from the high-voltage power supply unit 108 and an introduction amount of the gas introduced from the gas pipe 206 are set via the control unit 107.
S412: Sample processing is started.
S413: The sample processing is ended, and the sample chamber 109 is opened to the atmosphere. After the opening to the atmosphere, the sample 120 is taken out from the sample stage 102.

If the deviation in the processing target position of the sample 120 has a margin of error that checking does not need to be performed for each sample, the checking steps (S407 to S410) performed by the second finder 106 may be omitted.

Although the invention made by the present inventor has been specifically described based on embodiments, the invention is not limited to the embodiments described above, and various modifications can be made without departing from the gist of the invention. The accuracy and precision of the processing can be further improved by providing, for example, an alignment mechanism (ion source position adjustment mechanism) capable of adjusting a position of the ion source in three directions perpendicular to one another.

### REFERENCE SIGNS LIST

100: ion milling device
101: ion source
102: sample stage
103: rotation stage
104: three-axis drive stage
105: first finder
106: second finder
107: control unit
108: high-voltage power supply unit
109: sample chamber
110: vacuum exhaust unit
120: sample
201: first cathode
202: second cathode
203: anode
204: permanent magnet
205: acceleration electrode
206: gas pipe

1. An ion milling device comprising:
a sample chamber;
a sample stage tiltable about a tilt axis and configured to allow a sample to be placed thereon via a rotation stage rotating about a rotation axis and a three-axis drive stage that can be driven in three axial directions perpendicular to one another;
an ion source configured to emit an unfocused ion beam to the sample and attached to the sample chamber such that an ion beam center of the ion beam is perpendicular to the tilt axis; and
a first finder, wherein
an optical system of the first finder is disposed on the sample stage such that an optical axis of the optical system coincides with the tilt axis.

2. The ion milling device according to claim 1, wherein
the optical system of the first finder is equipped with a reticle that displays a cross line indicating a position of the optical axis of the optical system.

3. The ion milling device according to claim 2, further comprising:
a control unit configured to drive the rotation stage and the three-axis drive stage.

4. The ion milling device according to claim 3, wherein
the rotation axis is perpendicular to the tilt axis and parallel to a first axial direction which is one of the three axial directions in which the three-axis drive stage is driven, and
the control unit drives the three-axis drive stage in the first axial direction such that a surface of the sample coincides with the cross line of the reticle on an image in the first finder.

5. The ion milling device according to claim 3, further comprising:
a second finder, wherein
an optical system of the second finder is disposed in the sample chamber such that an optical axis of the optical system is perpendicular to a plane extending between the tilt axis and the ion beam center.

6. The ion milling device according to claim 5, wherein
the rotation axis is perpendicular to the tilt axis and parallel to a first axial direction which is one of the three axial directions in which the three-axis drive stage is driven, and
the control unit drives the three-axis drive stage in one or both of the two axial directions perpendicular to the first axial direction such that a processing target position of the sample is located on the rotation axis on an image in the second finder.

7. The ion milling device according to claim 5, wherein
the rotation axis is perpendicular to the tilt axis and parallel to a first axial direction which is one of the three axial directions in which the three-axis drive stage is driven, and
the control unit rotates the rotation stage to rotate the sample, and drives the three-axis drive stage in one or both of the two axial directions perpendicular to the first axial direction such that a processing target position of the sample appears to be stationary on an image in the second finder.

8. The ion milling device according to claim 1, wherein
the ion source is attached to the sample chamber via an ion source position adjustment mechanism configured to adjust a position in three directions perpendicular to one another.

9. A processing method of processing a sample using an ion milling device including a sample chamber, a sample stage tiltable about a tilt axis and configured to allow the sample to be placed thereon via a rotation stage rotating about a rotation axis and a three-axis drive stage that can be driven in three axial directions perpendicular to one another, an ion source configured to emit an unfocused ion beam to the sample and attached to the sample chamber such that an ion beam center of the ion beam is perpendicular to the tilt axis, and a first finder, the processing method comprising:
disposing an optical system of the first finder on the sample stage such that an optical axis of the optical system coincides with the tilt axis;
evacuating an inside of the sample chamber after placing the sample on the sample stage;
driving the three-axis drive stage such that a surface of the sample coincides with the optical axis of the optical system of the finder on an image in the first finder; and
emitting the ion beam from the ion source toward the sample after tilting the sample stage at a predetermined angle.

10. The processing method according to claim 9, wherein
the optical system of the first finder is equipped with a reticle that displays a cross line indicating a position of the optical axis of the optical system,
the rotation axis is perpendicular to the tilt axis and parallel to a first axial direction which is one of the three axial directions in which the three-axis drive stage is driven, and
the surface of the sample coincides with the optical axis of the optical system of the finder by driving the three-axis drive stage in the first axial direction such that the surface of the sample coincides with the cross line of the reticle on the image in the first finder.

11. The processing method according to claim 9, wherein
the ion milling device includes a second finder,
an optical system of the second finder is disposed in the sample chamber such that an optical axis of the optical system is perpendicular to a plane extending between the tilt axis and the ion beam center, and
after the sample stage is tilted at the predetermined angle, the three-axis drive stage is driven such that a processing target position of the sample is located on the rotation axis on an image in the second finder.

12. The processing method according to claim 11, wherein
the rotation axis is perpendicular to the tilt axis and parallel to a first axial direction which is one of the three axial directions in which the three-axis drive stage is driven, and
a processing target position of the sample is located on the rotation axis by rotating the rotation stage to rotate the sample, and driving the three-axis drive stage in one or both of the two axial directions perpendicular to the first axial direction such that the processing target position of the sample appears to be stationary on an image in the second finder.
